(19) United States
(12) Patent Application Publication
(10) Pub. No.: US 2009/0001485 A1
(43) Pub. Date: Jan. 1, 2009

(54) Semiconductor Device and Manufacturing Method Thereof

(76) Inventors: Ji Hong Kim, Dongjak-gu (KR); Duck Ki Jang, Bucheon-si (KR); Byung Tak Jang, Seongnam-si (KR); Song Hee Park, Dongjak-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/145,860

(22) Filed: Jun. 25, 2008

(30) Foreign Application Priority Data
Jun. 26, 2007 (KR) 10-2007-0062630

(51) Int. Cl. H01L 21/336; H01L 29/78

(52) U.S. Cl. 257/408; 438/294; 257/E29.266; 257/E21.409

(57) ABSTRACT

Disclosed is a semiconductor device that can be used as a high voltage transistor. The semiconductor device can include a gate electrode on a semiconductor substrate, drift regions in the substrate at opposite sides of the gate electrode, a source region in one of the drift regions and a drain region in the other of the drift regions, and a shallow trench isolation (STI) region in a portion of the drift region between the gate electrode and the drain region. The portion of the drift region below the STI region can have a doping profile in which the concentration of impurities decreases from the concentration at the lower surface of the STI region, and then increases, and then again decreases.

### RELATED APPLICATION

The application claims priority under 35 U.S.C. § 119(e) of Korean Patent Application No. 10-2007-0062630, filed, Jun. 26, 2007, which is hereby incorporated by reference in its entirety.

### BACKGROUND

As semiconductor devices are being fabricated in increasingly smaller sizes, the size of a high voltage device has also been gradually reduced.

However, a high voltage device should be able to maintain the same performance capabilities regardless of the size thereof. In addition, it is preferable to provide a manufacturing method compatible with the manufacturing process of a low voltage device.

One difficulty in fabricating the smaller high voltage device is a breakdown phenomenon that may occur in the high voltage device due to a snapback phenomenon.

In detail, if voltage applied to the drain of a high voltage transistor is increased, electrons move from the source of the high voltage transistor to its drain. Thus, impact ionization may occur around the lower portion of a spacer located at a side of the gate electrode of the high voltage transistor in the drain direction.

As the impact ionization occurs, holes move toward the substrate from below the spacer, so that electric current flows through the substrate. Thus, the amount of the electric current flowing from the drain to the source suddenly increases, causing the snapback phenomenon. Consequently, BV (breakdown voltage) characteristics may deteriorate.

### BRIEF SUMMARY

Embodiments of the present invention relate to a semiconductor device and a method for manufacturing the same.

An embodiment of the present invention relates to a semiconductor device having an improved breakdown voltage characteristic and a method for manufacturing the same. Certain embodiments of the present invention can provide high voltage devices.

In addition, an embodiment of the present invention can provide a semiconductor device capable of inhibiting impact ionization from occurring, and a method for manufacturing the same.

A semiconductor device according to an embodiment includes a gate electrode on a semiconductor substrate, drift regions provided in the substrate at opposite sides of the gate electrode, a source region in the drift region at a first side of the gate electrode and a drain region in the drift region at the other side of the gate electrode, and an STI region in the drift region and located between the gate electrode and the drain region. The portion of the drift region beginning at a lower portion of the STI region has a doping profile in which concentration of impurities decreases, then increases, and then again decreases in a downward direction from the lower portion of the STI region.

A method for manufacturing a semiconductor device according to an embodiment includes forming a first impurity region by implanting first conductive type impurities into a second conductive type semiconductor substrate at a first implantation energy; forming a second impurity region above the first impurity region by implanting first conductive type impurities into the semiconductor substrate at a second implantation energy; heat treating the semiconductor substrate to form drift regions by diffusing the first and second impurity regions; forming a gate electrode on the semiconductor substrate in a region between adjacent drift regions; implanting first conductive type impurities at a high concentration into the drift regions to form a source region at one side of the gate electrode and a drain region at the other side of the gate electrode; and forming an STI region by selectively etching a portion of the drift region between the gate electrode and the drain region and filling the etched portion with insulating material.

### BRIEF DESCRIPTION OF THE DRAWINGS

FIG. 1 is a cross-sectional view illustrating a semiconductor device according to an embodiment of the present invention.

FIG. 2 is a graph illustrating a doping profile of a drift region for a semiconductor device according to an embodiment of the present invention.

FIGS. 3 to 8 are cross-sectional views for illustrating a method for manufacturing a semiconductor device according to an embodiment of the present invention.

FIG. 9 is a graph illustrating on-breakdown voltage characteristics of a semiconductor device fabricated according to an embodiment of the present invention.

FIGS. 10 and 11 are graphs illustrating the characteristics of a drift drive process as a function of time in a semiconductor device fabricated according to an embodiment of the present invention.

### DETAILED DESCRIPTION

Hereinafter, a semiconductor device and a method for manufacturing the same according to an embodiment will be described with reference to the accompanying drawings.

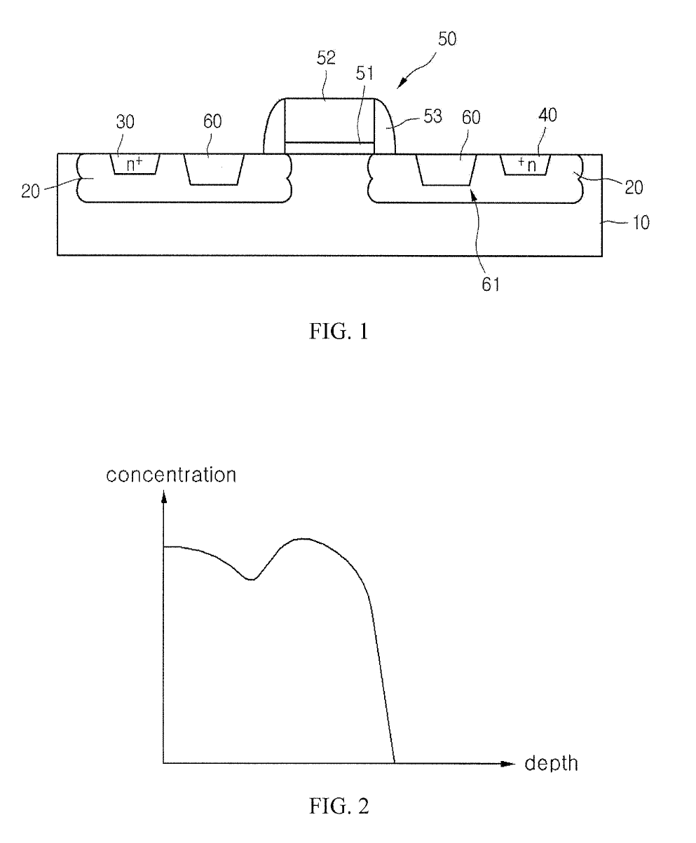

Referring to FIG. 1, a semiconductor device can include drift regions 20 formed in a semiconductor substrate 10. In one embodiment, the semiconductor substrate 10 can be P-type and the drift regions 20 can be formed of N-type impurities.

A gate electrode 50 can be provided on the substrate 10 between the drift regions 20. The gate electrode 50 can include a gate insulating layer 51, a gate poly 52, and a spacer 53. The gate poly 52 can be formed of polysilicon, metal, silicide, or a combination thereof.

A source region 30 and a drain region 40 are provided in respective portions of the drift regions 20 at each side of the gate electrode 50. The drift regions 20 can have a doping profile in which the concentration of impurities gradually increases and then decreases, and then again gradually increases and then decreases in the downward direction from the surface of the semiconductor substrate 10.

A shallow trench isolation (STI) region 60 is provided in the drift region 20 between the gate electrode 50 and the source region 30, and in the drift region 20 between the gate electrode 50 and the drain region 40.

The drift region 20 is used to reduce the intensity of the electric field between the gate electrode 50 and the drain region 40.

To function in this capacity, a drift region must have a sufficient width to the extent that the drift region can increase the interval between the gate electrode and the drain region. However, the width of the drift region is constrained by the desire to fabricate smaller sized semiconductor devices. In addition, the drift regions create a reduction of electric current between the gate and the drain, and the gate voltage is being increased. Accordingly, there is a need to reduce the widths of the drift regions.

According to embodiments of the present invention, the widths of the drift regions 20 can be reduced by forming STI regions 60 in the drift regions 20.

By forming STI region 60 in each drift region 20, the width of the drift region 20 can be reduced, and the intensity of the electric field between the gate electrode 50 and the drain region 40 can also be reduced.

Meanwhile, a safe operating area (SOA), which is a characteristics of a power device, is determined by both the breakdown voltage measured when voltage applied to the drain region 40 is increased in a state in which the gate electrode 50, the source region 30 and the semiconductor substrate 10 are grounded, and the on-breakdown voltage (BVon) measured when voltage applied to the drain region 40 is increased in a state in which the source region 30 and the semiconductor substrate 10 are grounded and operating voltage is applied to the gate electrode 50.

The breakdown voltage and on-breakdown voltage characteristics may cause a trade-off phenomenon according to the doping profile of the drift regions 20.

According to an embodiment, the breakdown voltage and on-breakdown voltage characteristics can be independently controlled. In detail, according to an embodiment, the doping concentration of the drift regions 20 is maintained to cause the breakdown voltage characteristics to be constant, and the doping profile of the drift regions 20 is varied to improve the on-breakdown voltage characteristics.

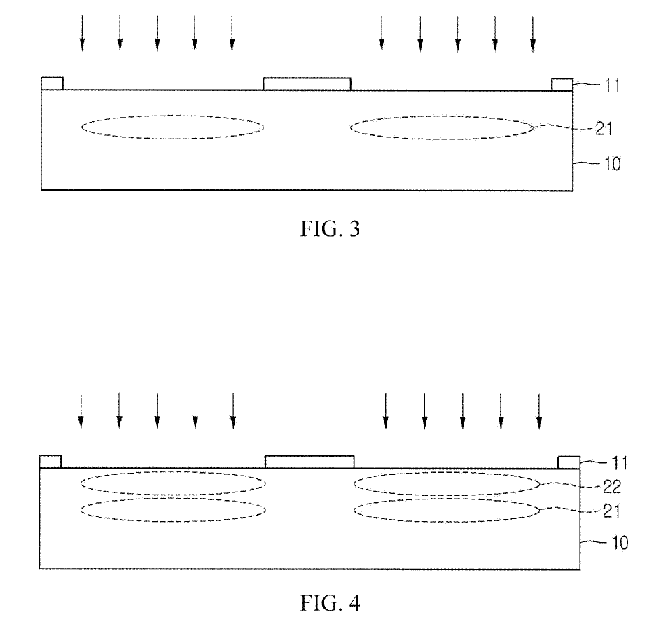

FIG. 2 is a graph illustrating the doping profile of a drift region, moving in the downward direction from a bottom surface of an STI region according to an embodiment of the present invention.

As shown in FIG. 2, a portion of the drift region 20 starting at a bottom surface of the STI region and moving in the depth direction can have a doping profile where the impurity concentration gradually decreases from the concentration at the bottom surface of the STI region, and then increases in concentration, and then again decreases in concentration.

According to one embodiment, the doping profile can be accomplished by performing a two-step impurity implantation process. The two-step impurity implantation process can be performed with a first implantation step and a second implantation step using the same dose of impurities but different implantation energies. In a specific embodiment, N-type ions, such as phosphorous ions, can be implanted using an implantation energy of 500 KeV and then an implantation energy of 180 KeV. After performing the two-step impurity implantation process, a heat treatment process can be performed to diffuse the dopants.

Referring back to FIG. 1, for a semiconductor device in which the STI region 60 is formed in the drift region 20, the strongest electric field occurs at the lower portion 61 of the STI region 60 adjacent to the drain region 40.

In such a state, as voltage is applied to the gate electrode 50, electrons flow toward the drain region 40 from the source region 30 via the drift region 30 below the lower portion 61 of the STI region 60. Thus, impact ionization may occur at the lower portion 61 of the STI region 60 adjacent to the drain region 40.

However, by creating a drift region 20 having the doping profile such as shown in FIG. 2, electrons can be distributed by shifting the movement path of electrons in the depth direction from the lower portion 61 of the STI region 60. Therefore, the impact ionization and snapback phenomenon can be inhibited from occurring.

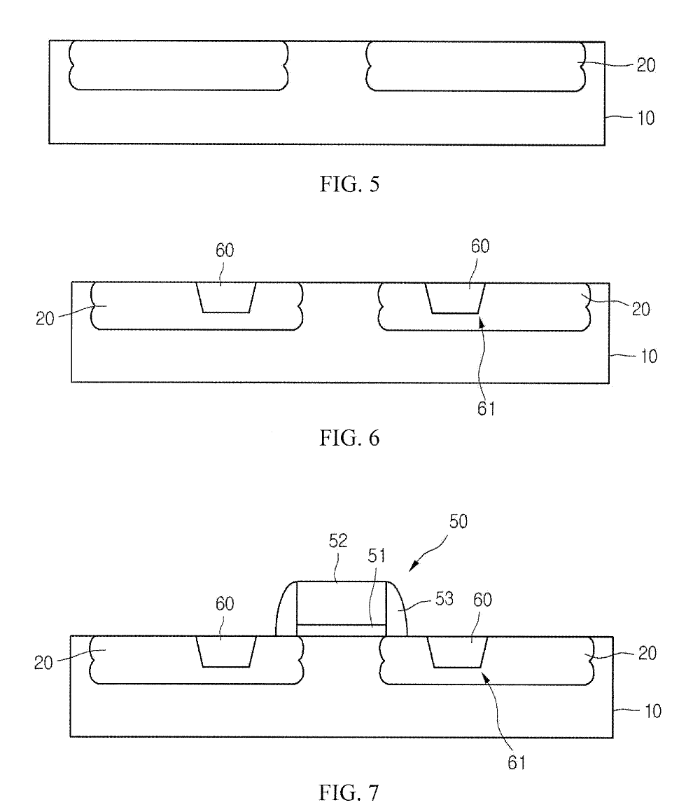

FIGS. 3 to 8 are cross-sectional views illustrating a method for manufacturing a semiconductor device according to an embodiment.

Referring to FIG. 3, a mask layer 11 can be formed on a semiconductor substrate 10. A first impurity region 21 can be formed by implanting ions into exposed regions of the substrate. In an embodiment, the ions can be N-type ions implanted into a P-type substrate. In one embodiment, the ions can be phosphorous (P) ions implanted into the semiconductor substrate 10 with an implantation energy of between about 400 KeV and about 600 KeV. In a specific embodiment, the P ions can be implanted into the semiconductor substrate 10 using an implantation energy of 500 KeV.

Referring to FIG. 4, a second impurity region 22 can be formed in the substrate exposed by the mask layer 11 above the first impurity region 21. In one embodiment, the second impurity region 22 can be formed by implanting the P ions into the semiconductor substrate 10 using an implantation energy of between about 130 KeV and about 230 KeV. In a specific embodiment, the P ions can be implanted into the semiconductor substrate 10 using an implantation energy of 180 KeV. The same dose of P ions can be used for the first impurity region implantation process and the second impurity region implantation process.

Referring to FIG. 5, a drift drive process can be performed to remove the mask layer 11 and heat-treat the semiconductor substrate 10. Heat treating the substrate diffuses the impurities in the first and second impurity regions 21 and 22 to form the drift regions 20.

In an embodiment, the drift drive process can be performed for about 40 minutes to about 50 minutes. In one embodiment, the drift drive process can be performed for 45 minutes.

Referring to FIG. 6, a region in each drift region 20 can be selectively removed to form a trench. Then, insulating material can be filled in the trench in the drift region 20 to form an STI region 60 in the drift region 20.

Referring to FIG. 7, a gate electrode 50 can be formed on a region of the substrate between drift regions 20. The gate electrode 50 can include a gate insulating layer 51, a gate poly 52 and a spacer 53, and can be formed by any suitable method known in the art.

Referring to FIG. 8, a source region and a drain region can be formed by implanting ions at a high concentration into the drift regions 20. This can be accomplished, for example, by forming source/drain mask patterns on the substrate, and implanting ions using the source/drain mask patterns as ion implantation masks. In an embodiment, the ions used for forming the source and drain regions can be N-type ions such as P ions.

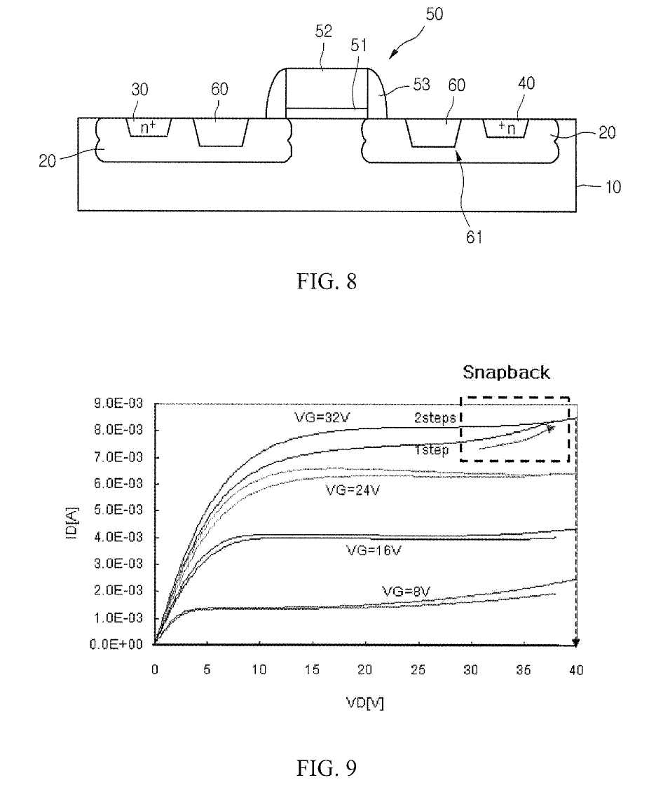

FIG. 9 is a graph illustrating the on-breakdown voltage characteristics of a semiconductor device fabricated according to an embodiment.

In FIG. 9, a horizontal axis represents drain voltage VD and a vertical axis represents drain current ID.

FIG. 9 also shows a comparison of a first case, in which the drift regions 20 are formed using a two-step impurity implantation according to an embodiment of the present invention, and a second case, in which the drift regions 20 are formed using a one-step impurity implantation.

In the case in which the one-step impurity implantation is performed and the gate voltage (VG) is 32 V (labeled 1 step), when the drain voltage (VD) becomes greater than 28 V, the drain current suddenly increases. This phenomenon is called snapback.

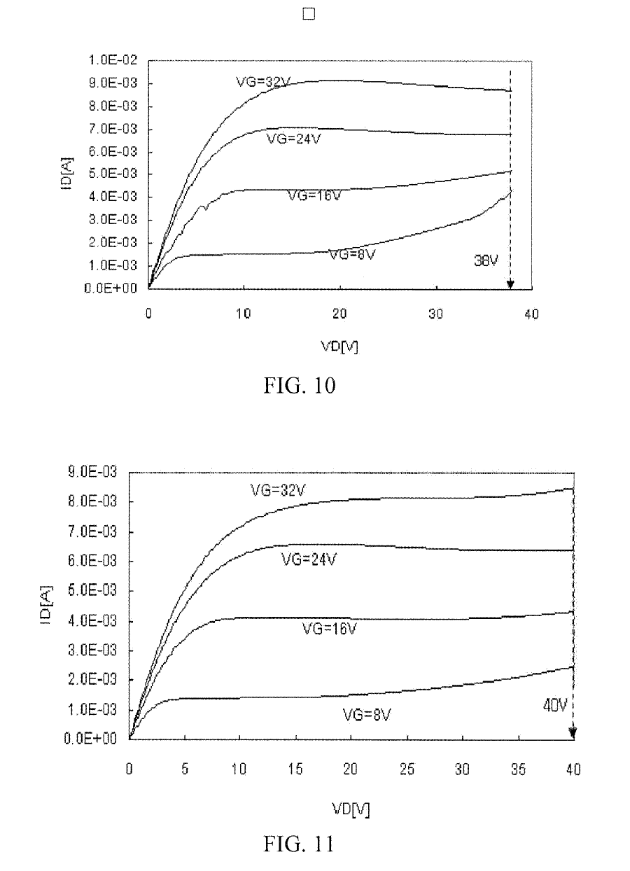

FIGS. 10 and 11 are graphs illustrating the effects of the drift drive process as a function of time on the characteristics of a semiconductor device fabricated according to an embodiment of the present invention.

FIG. 10 shows a case in which the drift drive process is performed for 30 minutes and FIG. 11 shows a case in which the drift drive process is performed for 45 minutes.

Referring to FIG. 10, in the case in which the drift drive process is performed for 30 minutes, junction breakdown occurs when the drain voltage VD is 38V, so that channel bonding may occur.

However, referring to FIG. 11, in the case in which the drift drive process is performed for 45 minutes, although the drain voltage VD is greater than 40V, the snapback phenomenon does not appear to have occurred. This represents that the breakdown voltage characteristics are improved by increasing the breakdown margin through increase in the drift drive process time after increasing the junction.

Therefore, in accordance with an embodiment of the present invention, a semiconductor device can be fabricated having improved breakdown voltage characteristics.

In addition, embodiments of the present invention provide a semiconductor device capable of inhibiting impact ionization from occurring, and the method for manufacturing the same.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a gate electrode on a semiconductor substrate;
a first drift region in the semiconductor substrate at a first side of the gate electrode;
a second drift region in the semiconductor substrate at a second side of the gate electrode;
a source region in the first drift region;
a drain region in the second drift region; and
a shallow trench isolation region in the second drift region between the gate electrode and the drain region,
wherein a doping profile of drift region impurities beginning at a bottom surface of the shallow trench isolation region and moving in the depth direction follows a profile of a decreasing impurity concentration, and then an increasing impurity concentration, and then again a decreasing impurity concentration.

2. The semiconductor device according to claim 1, wherein the drift region impurities comprise phosphorous ions.

3. The semiconductor device according to claim 2, wherein the source region and drain region comprise phosphorous ions.

4. The semiconductor device according to claim 1, wherein the first drift region and the second drift region are provided in the semiconductor substrate spaced apart below the gate electrode.

5. A method for manufacturing a semiconductor device, comprising:
forming a first impurity region in a semiconductor substrate by implanting impurities into the semiconductor substrate at a first implantation energy;
forming a second impurity region in the semiconductor substrate above the first impurity region by implanting impurities into the semiconductor substrate at a second implantation energy;
diffusing the first and second impurity regions by heat treating the semiconductor substrate to form drift regions;
forming a gate electrode on the semiconductor substrate;
forming a source region in a first drift region of the drift regions and a drain region in a second drift region of the drift regions by implanting impurities into a portion of the first and second drift regions, wherein the first drift region is at a first side of the gate electrode and the second drift region is at a second side of the gate electrode; and
forming a shallow trench isolation region in a portion of the second drift region between the gate electrode and the drain region.

6. The method according to claim 5, wherein the first implantation energy is about 400 KeV to about 600 KeV.

7. The method according to claim 5, wherein the second implantation energy is about 130 KeV to about 230 KeV.

8. The method according to claim 5, wherein the heat treating of the semiconductor substrate is performed for between about 40 minutes and about 50 minutes.

9. The method according to claim 5, wherein a doping profile of the second drift region, beginning at a bottom surface of the shallow trench isolation region and moving in the depth direction, follows a profile of a decreasing impurity concentration, and then an increasing impurity concentration, and then again a decreasing impurity concentration.

10. The method according to claim 5, wherein forming the first impurity region comprises implanting phosphorous ions into the semiconductor substrate at the first implantation energy.

11. The method according to claim 10, wherein forming the second impurity region comprises implanting phosphorous ions into the semiconductor substrate at the second implantation energy.

12. The method according to claim 11, wherein the phosphorous ions for forming the second impurity region are implanted at a same dose as that for forming the first impurity region.

13. The method according to claim 11, wherein forming the source region and the drain region comprises implanting phosphorous ions.

14. The method according to claim 5, further comprising:
forming a drift region mask layer before forming the first impurity region and the second impurity region,
wherein during the forming of the first impurity region and the forming of the second impurity region, the drift region mask layer is used as an implantation mask.

15. The method according to claim 14, wherein during the heat treating of the semiconductor substrate to form drift regions, the drift region mask layer is removed.
